(19) United States
(12) Patent Application Publication
(10) Pub. No.: US 2011/0140210 A1
(43) Pub. Date: Jun. 16, 2011

(54) MICROELECTROMECHANICAL SENSOR DEVICE PACKAGE AND METHOD FOR MAKING THE SAME

(75) Inventors: Jeff Biar, Taipei County (TW); Ming-Ching Wu, Taipei County (TW)

(73) Assignee: DOMINTECH CO., LTD., Wugu Township (TW)

(21) Appl. No.: 12/834,386

(22) Filed: Jul. 12, 2010

(30) Foreign Application Priority Data
Dec. 14, 2009 (TW) 98142787

(51) Int. Cl. H01L 29/84; H01L 21/50; H01L 21/78

(52) U.S. Cl. 257/415; 438/51; 257/E29.324; 257/E21.499; 257/E21.599

(57) ABSTRACT

A microelectromechanical sensor device package includes a substrate, a microelectromechanical sensor device and a cap. The substrate has a surface on which a circuit pattern having a plurality of first conductive contacts is provided. The device is mounted on the surface of the substrate and has an active surface on which a plurality of second conductive contacts are provided. A plurality of bonding wires are used to electrically connect the first conductive contacts to the second conductive contacts respectively. The cap is made of an electrically insulating material and attached on the surface of the substrate in a way that the cap covers the microelectromechanical sensor device and a space is formed between the cap and the microelectromechanical sensor device.

### BACKGROUND OF THE INVENTION

1. Field of the Invention

The present invention relates generally to microelectromechanical sensor devices and more particularly, to a microelectromechanical sensor device package that can block interference of ambient environment, and the method for making the same.

2. Description of the Related Art

How to prevent a microelectromechanical sensor device from environment interference and to protect the breakable and sensitive structure of the sensor device is always an issue to be resolved. U.S. Pat. No. 7,443,017 disclosed a package having a substrate served as a cap and bonded on a microelectromechanical sensor wafer in the process of the wafer-level production. However, because of the inherent warpage problem of the wafer, bonding two wafers together may cause internal stress affecting the precision and accuracy of the sensor chip. In addition, the shrinking strength of the plastic material due to curing in molding process may shift the sensing characteristics of the sensor chip.

In the light of the above, it is desired to provide a package that can prevent the microelectromechanical sensor device from environment interference and protect the breakable and sensitive structure of the device.

### SUMMARY OF THE INVENTION

The present invention has been accomplished in view of the above-noted circumstances. It is therefore an objective of the present invention to provide a package that can prevent the microelectromechanical sensor chip from environment interference.

Another objective of the present invention is to provide a package that can effectively protect the microelectromechanical sensor chip from damage.

To attain the above-mentioned objectives, the present invention provides a microelectromechanical sensor device package comprising a substrate, a microelectromechanical sensor device and a cap. The substrate has a surface on which a circuit pattern having a plurality of first conductive contacts is provided. The microelectromechanical sensor device is mounted on the surface of the substrate and has an active surface on which a plurality of second conductive contacts are provided. A plurality of bonding wires, each of which has a first end electrically connected with one of the first conductive contacts, and a second end electrically connected with one of the second conductive contacts, are provided for electrical connection. The cap is made of an electrically insulating material and attached on the surface of the substrate in a way that the cap covers the microelectromechanical sensor device and a space is formed between the cap and the microelectromechanical sensor device.

Another aspect of the present invention is to provide a method for packaging microelectromechanical sensor devices, which comprises the steps of providing a microelectromechanical sensor wafer, cutting the microelectromechanical sensor wafer into a plurality of microelectromechanical sensor chips, spacedly mounting the microelectromechanical sensor chips on a substrate and electrically connecting the microelectromechanical sensor chips with the substrate, and attaching a cap of electrically insulating material on the substrate in a way that the cap covers the microelectromechanical sensor chips respectively and a space is formed between the cap and each of the microelectromechanical sensor chips.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWING

The present invention will become more fully understood from the detailed description given herein below and the accompanying drawings which are given by way of illustration only, and thus are not limitative of the present invention, and wherein:

FIG. 1 is a schematic sectional view of a microelectromechanical sensor device package in accordance with a first preferred embodiment of the present invention;

FIG. 2 is a schematic sectional view of a microelectromechanical sensor device package in accordance with a second preferred embodiment of the present invention;

FIG. 3 is a schematic sectional view of a microelectromechanical sensor device package in accordance with a third preferred embodiment of the present invention;

FIG. 4 is a schematic sectional view of a microelectromechanical sensor device package in accordance with a fourth preferred embodiment of the present invention;

FIG. 5 is a schematic drawing showing a wafer used in a step of a method for making a microelectromechanical sensor device package in accordance with a preferred embodiment of the present invention;

FIG. 6 is a schematic drawing showing a second step of the method in accordance with the preferred embodiment of the present invention;

FIG. 7 is a schematic drawing showing a third step of the method in accordance with the preferred embodiment of the present invention; and

FIG. 8 is a schematic drawing showing a fourth step of the method in accordance with the preferred embodiment of the present invention.

### DETAILED DESCRIPTION OF THE INVENTION

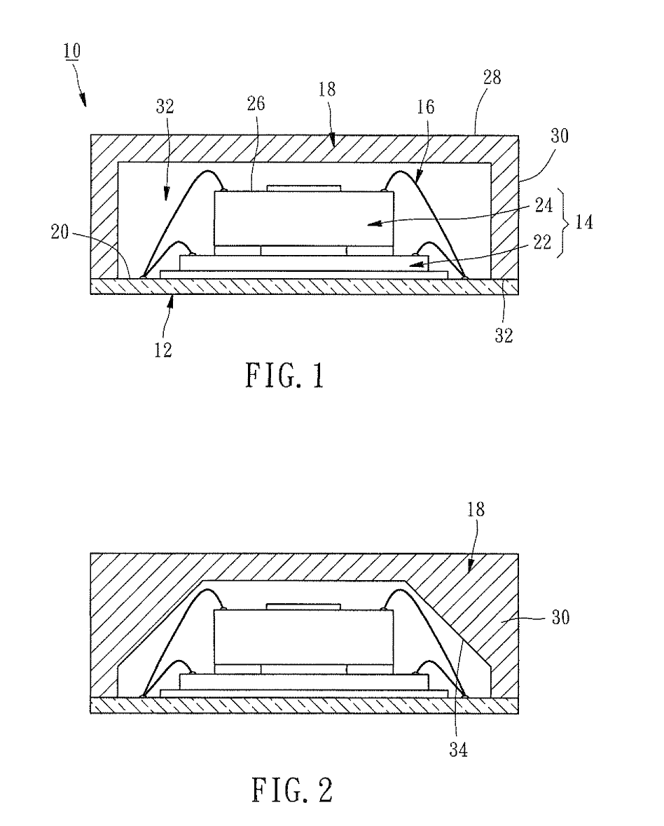

As shown in FIG. 1, a microelectromechanical sensor device package, provided by a first preferred embodiment of the present invention and denoted with a reference numeral 10, comprises a substrate 12, a microelectromechanical sensor device 14, a plurality of bonding wires 16 and a cap 18.

The substrate 12 is made of an electrically insulating material and provided with a top surface 20 on which a circuit pattern (not shown in the drawing) is presented. The microelectromechanical sensor device 14 is composed of a circuit chip 22 and a sensor chip 24 stacked on the circuit chip 22. The sensor chip 24 has an active surface 26. It will be appreciated that the microelectromechanical sensor device 14 mentioned in the present invention is a well-known prior art; therefore, no detailed description of the device 14 needs to be further recited hereinafter. However, the structure of the microelectromechanical sensor device 14 is not limited to the aforesaid one.

By means of the bonding wires 16, the electrical connections between the circuit chip 22 and the substrate 12 and between the sensor chip 24 and the substrate 12 can be realized. Similarly, using bonding wires to electrically connecting conductive contacts is well-known; therefore, a detailed description thereof is not necessary for a person skilled in the art.

The cap 18 is made of a plastic material by molding, and provided with a top wall 28 and an annular periphery wall 30 extending downwardly from an edge of the top wall 28, such that the cap 18 has substantially an inverted U-shaped crosssection. A bottom 30 of the annular periphery wall 30 of the cap 18 is attached on the top surface 20 of the substrate 12, such that the microelectromechanical sensor device 14 is covered by the cap 18 and a space 32 is defined between the microelectromechanical sensor device 14 and the cap 18.

As above-described, the cap 18 of the microelectromechanical sensor device package 10 is not only provided with a space 32 for facilitating the sensor chip 24 to perform the sensing activity but also can block the interference originated from an ambient environment and not supposed to be detected by the sensor chip 24. Further, since the cap 18 is attached on the substrate 12, the internal stress problem of the prior art can be eliminated.

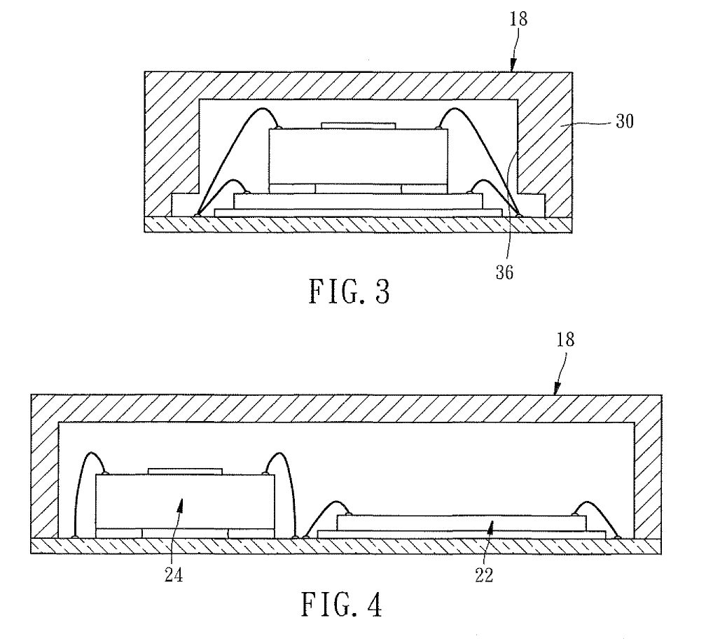

In order to enhance the mechanical strength of the package, the inner surface of the annular periphery wall 30 of the cap 18 can be made having a trapezoid shaped crosssection, as shown in FIG. 2, or a stepped crosssection, as shown in FIG. 3. Further, as shown in FIG. 4, the circuit chip 22 and the sensor chip 24 can be mounted on the substrate 12 side by side, not stacked together.

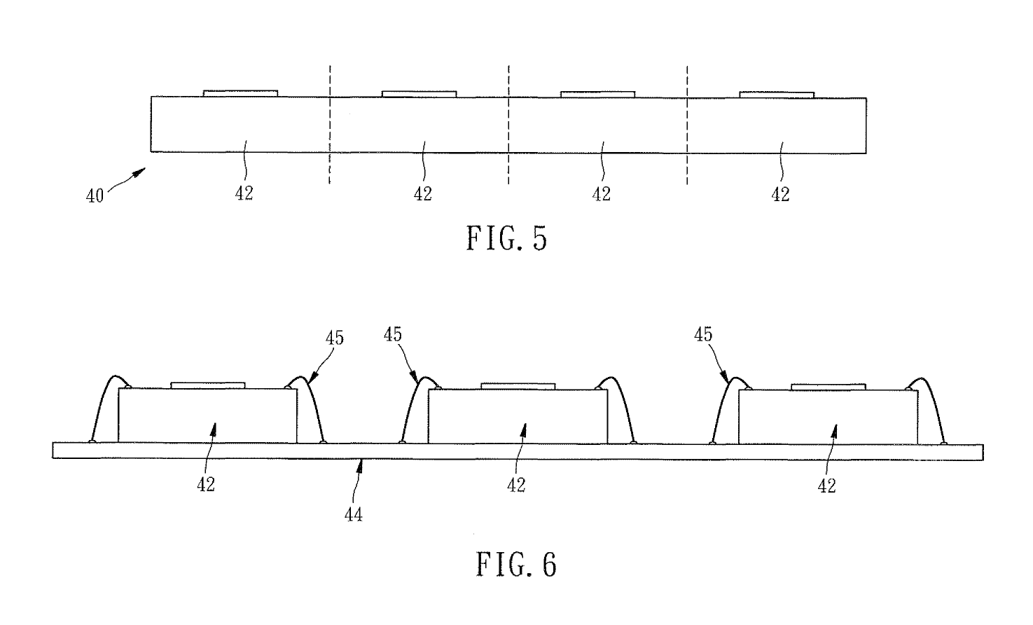

The structure and technical features of the package of the present invention have been detailed described hereinbefore. Hereunder, a method for making a microelectromechanical sensor device package comprising the following steps will be illustrated by reference to FIGS. 5-8.

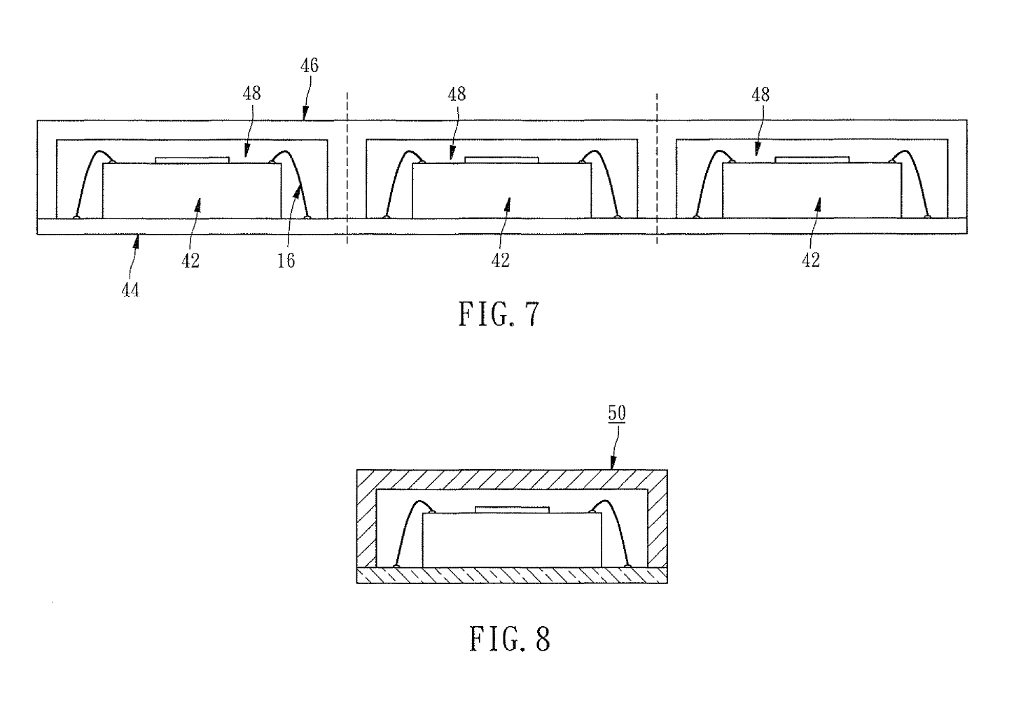

As shown in FIG. 5, a microelectromechanical sensor wafer 40 contains a plurality of microelectromechanical sensor chips 42 is firstly prepared and provided. Thereafter, the microelectromechanical sensor wafer 40 is cut into a plurality of individual microelectromechanical sensor chips 42 each having a predetermined size. And then, the chips 42 are spacedly mounted on a substrate 44 and electrically connected with the substrate 44 through bonding wires 45 by the bonding technique, as shown in FIG. 6. Thereafter, a cap 46, made of a plastic material by molding and having a plurality of individual chambers 48 each having a substantially inverted U-shaped crosssection, is attached on the substrate 44 in a way that a space is formed between each of the chambers 48 and one of the microelectromechanical sensor chips 42, as shown in FIG. 7. Finally, the combination of the cap 46 and the substrate 44 is cut into a plurality of microelectromechanical sensor device packages 50, as shown in FIG. 8.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A microelectromechanical sensor device package comprising:
a substrate having a surface on which a circuit pattern having a plurality of first conductive contacts is provided;
a microelectromechanical sensor device mounted on the surface of the substrate and having an active surface on which a plurality of second conductive contacts are provided;
a plurality of bonding wires each having a first end electrically connected with one of the first conductive contacts, and a second end electrically connected with one of the second conductive contacts, and
a cap made of an electrically insulating material and attached on the surface of the substrate in a way that the cap covers the microelectromechanical sensor device and a space is formed between the cap and the microelectromechanical sensor device.

2. The microelectromechanical sensor device package as claimed in claim 1, wherein the microelectromechanical sensor device comprises a circuit chip and a sensor chip stacked on the circuit chip.

3. The microelectromechanical sensor device package as claimed in claim 1, wherein the microelectromechanical sensor device comprises a circuit chip and a sensor chip, which are mounted on the surface of the substrate respectively.

4. The microelectromechanical sensor device package as claimed in claim 1, wherein the cap comprises a top wall and an annular periphery wall extending downwardly from the top wall and having a bottom attached on the surface of the substrate.

5. The microelectromechanical sensor device package as claimed in claim 1, wherein the cap is made of a plastic material by molding.

6. A method for packaging microelectromechanical sensor devices comprising the steps of:
providing a microelectromechanical sensor wafer;
cutting the microelectromechanical sensor wafer into a plurality of microelectromechanical sensor chips;
spacedly mounting the microelectromechanical sensor chips on a substrate and electrically connecting the microelectromechanical sensor chips with the substrate; and
attaching a cap of electrically insulating material on the substrate in a way that the cap covers the microelectromechanical sensor chips respectively and a space is formed between the cap and each of the microelectromechanical sensor chips.

7. The method as claimed in claim 6, wherein the substrate comprises a surface on which a circuit pattern having a plurality of first conductive contacts is provided; the microelectromechanical sensor chips each have an active surface on which a plurality of second conductive contacts are provided; the first and second conductive contacts are electrically and respectively connected through bonding wires.

8. The method as claimed in claim 6, wherein the cap comprises a top wall, an annular periphery wall extending downwardly from an edge of the top wall and having a bottom attached on the substrate, and a plurality of individual chambers forming the spaces.

9. The method as claimed in claim 6, wherein the cap is made of a plastic material by molding.
